(19) United States
(12) Patent Application Publication
(10) Pub. No.: US 2014/0097444 A1
(43) Pub. Date: Apr. 10, 2014

(54) NITRIDE SEMICONDUCTOR DEVICE

(71) Applicant: INDUSTRIAL TECHNOLOGY RESEARCH INSTIT, Hsinchu (TW)

(72) Inventors: Yen-Hsiang Fang, New Taipei City (TW); Chen-Zi Liao, Nantou County (TW); Rong Xuan, New Taipei City (TW); Chien-Pin Lu, Taoyuan County (TW); Yi-Keng Fu, Hsinchu County (TW); Chih-Wei Hu, Taoyuan County (TW); Hsun-Chih Liu, New Taipei City (TW)

(73) Assignee: INDUSTRIAL TECHNOLOGY RESEARCH INSTITUTE, Hsinchu (TW)

(21) Appl. No.: 13/647,399

(22) Filed: Oct. 9, 2012

(51) Int. Cl. H01L 33/32

(52) U.S. Cl. 257/76; 257/96; 257/E33.027

(57) ABSTRACT

A nitride semiconductor device includes a silicon substrate, a nucleation layer, a buffer layer, a first type nitride semiconductor layer, a light-emitting layer and a second type nitride semiconductor layer is provided. The nucleation layer is disposed on the silicon substrate. The buffer layer is disposed on the nucleation layer. The first type nitride semiconductor layer is disposed on the buffer layer. The first type nitride semiconductor layer is doped with a first type dopant, at least one of the buffer layer and the first type nitride semiconductor layer comprises a codopant distributed therein, and an atomic radius of the codopant is larger than an atomic radius of the first type dopant. The light-emitting layer is disposed on the first type nitride semiconductor layer. The second type nitride semiconductor layer is disposed on the light-emitting layer, the second type nitride semiconductor layer comprising a second type dopant.

### TECHNICAL FIELD

The technical field relates to a nitride semiconductor device. Particularly, the technical field relates to a nitride semiconductor device on silicon substrate.

### BACKGROUND

Light-emitting diodes (LEDs) are semiconductor devices made of a compound semiconductor material containing group elements, for example, GaN, GaP, GaAs, and the like. The lifespan of the LED is up to 100,000 hours, and has advantages of quick response speed (approximately 10⁻⁹ seconds), small volume, power-saving, low pollution, high reliability, and ease mass production. Thus, the LEDs have been intensively used in many fields, for example, illumination device, traffic lights, cellular phones, scanners, fax machines, etc.

FIG. 1 is a cross-sectional view schematically illustrating a conventional nitride semiconductor device. Referring to FIG. 1, the conventional nitride semiconductor device 100 comprises a silicon substrate 110, a nucleation layer 120, a buffer layer 130, a first type nitride semiconductor layer 140, a light-emitting layer 150 and a second type nitride semiconductor layer 160. The nucleation layer 120 is disposed on the silicon substrate 110. The buffer layer 130 is disposed on the nucleation layer 120. The first type nitride semiconductor layer 140 is disposed on the buffer layer 130. The light-emitting layer 150 is disposed on the first type nitride semiconductor layer 140. The second type nitride semiconductor layer 160 is disposed on the light-emitting layer 150.

In the prior art, sapphire (Al₂O₃) substrates are often used in GaN-based LEDs. However, thermal conductivity of sapphire substrates is not good enough. Accordingly, silicon substrates with better thermal conductivity are gradually used in fabrication of GaN-based LEDs. In addition to good thermal conductivity, the silicon substrates have many advantages, such as high electrical conduction, large wafer size and low cost.

During the fabrication of the conventional nitride semiconductor device 100 (e.g. GaN-based LEDs), the nucleation layer 120, the buffer layer 130, the first type nitride semiconductor layer 140, the light-emitting layer 150 and the second type nitride semiconductor layer 160 are grown at high temperature. After the nucleation layer 120, the buffer layer 130, the first type nitride semiconductor layer 140, the light-emitting layer 150 and the second type nitride semiconductor layer 160 are grown completely, a cooling process is then performed. During the manufacturing process, a stress resulted from thermal expansion coefficient (CTE) mismatch between the first type nitride semiconductor layer 140 (i.e. GaN-based III-V compound) and the silicon substrate 110 is generated, and the conventional nitride semiconductor device 100 suffers the stress. Due to the stress, the conventional nitride semiconductor device 100 bends severely and possibility of crack increases. Therefore, it is a great challenge in reducing the crack possibility caused by the excessive stress.

### SUMMARY

In this disclosure, the stress of the nitride semiconductor device can be slowed down so that the crack possibility of the nitride semiconductor device can be minimized.

One of exemplary embodiments provides a nitride semiconductor device. A nitride semiconductor device includes a silicon substrate, a nucleation layer, a buffer layer, a first type nitride semiconductor layer, a light-emitting layer and a second type nitride semiconductor layer is provided. The nucleation layer is disposed on the silicon substrate. The buffer layer is disposed on the nucleation layer. The first type nitride semiconductor layer is disposed on the buffer layer. The first type nitride semiconductor layer is doped with a first type dopant, at least one of the buffer layer and the first type nitride semiconductor layer comprises a codopant distributed therein, and an atomic radius of the codopant is larger than an atomic radius of the first type dopant. The light-emitting layer is disposed on the first type nitride semiconductor layer. The second type nitride semiconductor layer is disposed on the light-emitting layer, the second type nitride semiconductor layer comprising a second type dopant.

In order to make the disclosure comprehensible, several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional view schematically illustrating a conventional nitride semiconductor device.

FIG. 2A is a cross-sectional view schematically illustrating a nitride semiconductor device according to the first embodiment of the disclosure.

FIG. 2B is an optical microscope (OM) picture of the conventional nitride semiconductor device.

FIG. 2C is an optical microscope picture of a nitride semiconductor device with one lattice mismatch pair.

FIG. 2D is an optical microscope picture of the nitride semiconductor device of FIG. 2A.

FIG. 2E is a raman spectrum of the conventional nitride semiconductor device.

FIG. 2F is a raman spectrum of the nitride semiconductor device of FIG. 2A.

FIG. 3 is a cross-sectional view schematically illustrating an LED according the first embodiment of the disclosure.

FIG. 4 is a cross-sectional view schematically illustrating an LED according the second embodiment of the disclosure.

FIG. 5A is a cross-sectional view schematically illustrating a nitride semiconductor device according to the second embodiment of the disclosure.

FIG. 5B is an optical microscope picture of the nitride semiconductor device of FIG. 5A after growing the first type nitride semiconductor layer.

FIG. 6A is a cross-sectional view schematically illustrating a nitride semiconductor device according to the third embodiment of the disclosure.

FIG. 6B is an optical microscope picture of the conventional nitride semiconductor device after growing the first type nitride semiconductor layer.

FIG. 6C is an optical microscope picture of the nitride semiconductor device of FIG. 6A after growing the first type nitride semiconductor layer.

FIG. 7 is a cross-sectional view schematically illustrating a nitride semiconductor device according to the fifth embodiment of the disclosure.

FIG. 8A is a cross-sectional view schematically illustrating a nitride semiconductor device according to the sixth embodiment of the disclosure.

FIG. 8B is a scanning electron microscope (SEM) picture of the conventional nitride semiconductor device.

FIG. 8C is a scanning electron microscope picture of the nitride semiconductor device of FIG. 8A.

FIG. 9 is a cross-sectional view schematically illustrating a nitride semiconductor device according to the seventh embodiment of the disclosure.

### DETAILED DESCRIPTION OF EMBODIMENTS

Because the difference between the thermal expansion coefficient (CTE) mismatch between the first type nitride semiconductor layer 140 (i.e. GaN-based III-V compound) and the silicon substrate 110 in the conventional nitride semiconductor device 100 reaches 54%, the conventional nitride semiconductor device 100 suffers an excessive stress during the cooling process. The curvature of the conventional nitride semiconductor device 100 changes significantly. When the stress exceeds certain value, the conventional nitride semiconductor device 100 cracks. In order to minimize the crack possibility of the nitride semiconductor device mentioned above, a stress reducing stacked layer is proposed by the disclosure.

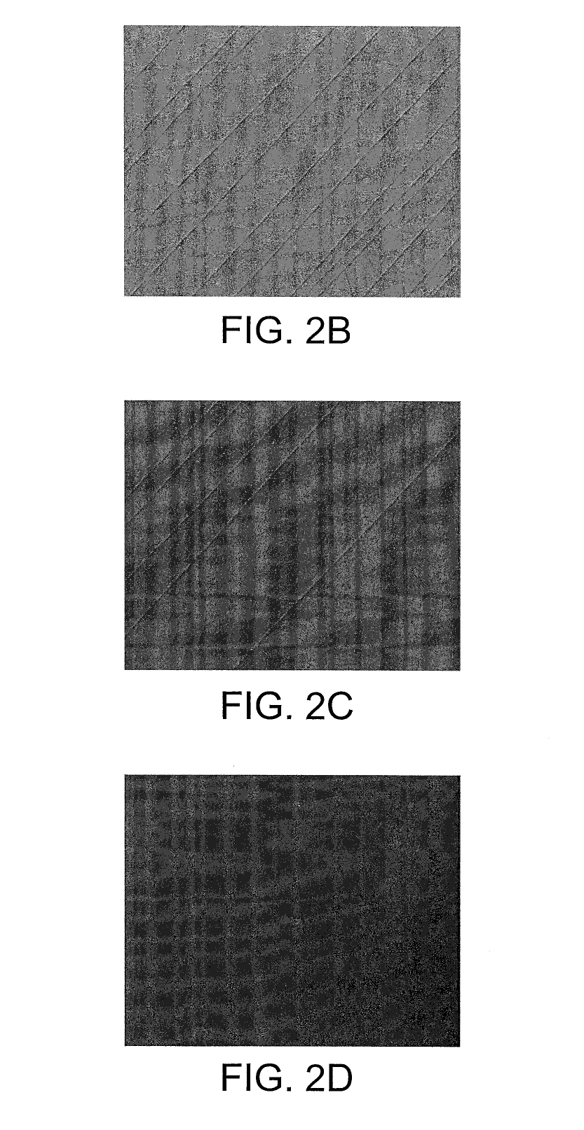

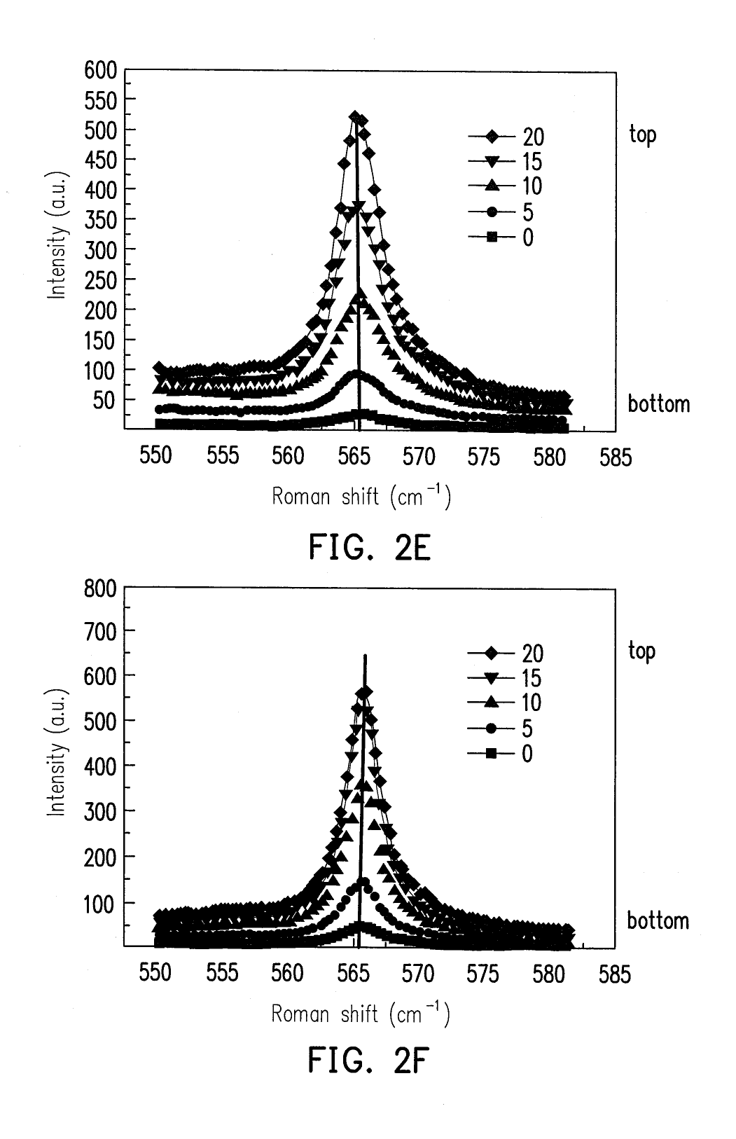

FIG. 2A is a cross-sectional view schematically illustrating a nitride semiconductor device according to the first embodiment of the disclosure. Referring to FIG. 2A, the nitride semiconductor device 200 includes a silicon substrate 210, a nucleation layer 220, a buffer layer 230, a first type nitride semiconductor stacked layer 240, a light-emitting layer 250 and a second type nitride semiconductor layer 260. The nucleation layer 220 is disposed on the silicon substrate 210. The buffer layer 230 is disposed on the nucleation layer 220. The first type nitride semiconductor stacked layer 240 is disposed on the buffer layer 230. The first type nitride semiconductor stacked layer 240 comprises a plurality of a lattice mismatch pairs, each of the lattice mismatch pairs comprises a plurality of first nitride semiconductor layers 242 and a plurality of second nitride semiconductor layers 244. The first nitride semiconductor layers 242 and the second nitride semiconductor layers 244 are stacked alternately, and the first nitride semiconductor layers 242 and the second nitride semiconductor layers 244 are different material. The light-emitting layer 250 is disposed on the first type nitride semiconductor stacked layer 240. The second type nitride semiconductor layer 260 is disposed on the light-emitting layer 250.

In this embodiment, the nucleation layer 220, the buffer layer 230, the first type nitride semiconductor stacked layer 240, the light-emitting layer 250 and the second type nitride semiconductor layer 260 are sequentially grown over the silicon substrate 210 by metal organic chemical vapor deposition (MOCVD) process. However, the fabrication process of the nucleation layer 220, the buffer layer 230, the first type nitride semiconductor stacked layer 240, the light-emitting layer 250 and the second type nitride semiconductor layer 260 is not limited to the above-mentioned MOCVD process, other suitable processes may be adapted in this disclosure. Besides, the nucleation layer 220 comprises an aluminium nitride (AlN) layer, for example.

In this embodiment, the buffer layer 230 comprises a graded AlGaN layer. In the graded AlGaN layer, a content of Al of the graded AlGaN layer gradually decreases from a first surface 232 of the buffer layer 230 to a second surface 234 of the buffer layer 230, wherein the first surface 232 is in contact with the nucleation layer 220, and the second surface 234 is in contact with the first type nitride semiconductor stacked layer 240. The variation rate of lattice constant divided by the thickness of the buffer layer 230 (the graded AlGaN layer) is from 5.08%/μm to 1.27%/μm.

For example, the first type nitride semiconductor stacked layer 240 is an n-type nitride semiconductor stacked layer, while the second type nitride semiconductor layer 260 is a p-type nitride semiconductor layer. An n-type dopant doped within the first nitride semiconductor layers 242 and the n-type dopant doped within the second nitride semiconductor layers 244 comprise at least one element of group IV A, respectively. In this embodiment, the n-type dopant doped within each first nitride semiconductor layers 242 and the n-type dopant doped within each second nitride semiconductor layers 244 are both silicon (Si), for example. However, the n-type dopant is not limited to silicon, other suitable elements may be used in this embodiment. A concentration of the n-type dopant doped within the first nitride semiconductor layers 242 is between about 1×10¹⁸/cm³ and about 5×10¹⁸/cm³, and a concentration of the n-type dopant doped within the second nitride semiconductor layers 244 is between about 1×10¹⁸/cm³ and about 5×10¹⁸/cm³. In this embodiment, the first type nitride semiconductor stacked layer 240 functions as an electron-provided layer and is in contact with the light-emitting layer 250. Besides, in this embodiment, the light-emitting layer 250 comprises multiple quantum wells, for example.

The first type nitride semiconductor stacked layer 240 comprises the first nitride semiconductor layers 242 and the second nitride semiconductor layers 244. The first nitride semiconductor layers 242 comprise a plurality of n-GaN layers, a plurality of n-Alₓ₁Ga_{y1}N layers or a plurality of n-Inₓ₂Ga_{y2}N layers, and the second nitride semiconductor layers 244 comprise a plurality of n-GaN layers, a plurality of n-Alₓ₃Ga_{y3}N layers or a plurality of n-Inₓ₄Ga_{y4}N layers, wherein x1 and x3 may be between about 0.02 and about 0.10 respectively, y1 and y3 may be between about 0.90 and about 0.98 respectively, x2 and x4 may be between about 0.01 and about 0.1 respectively, and y2 and y4 may be between about 0.9 and about 0.99 respectively. The first nitride semiconductor layers 242 and the second nitride semiconductor layers 244 are different material so as to form the lattice mismatch pairs.

In this embodiment, the first nitride semiconductor layers 242 comprise a plurality of n-GaN layers, and the second nitride semiconductor layers 244 comprise a plurality of n-Alₓ₁Ga_{y1}N layers, wherein x1 is 0.08 and, y1 is 0.92. However, the values of x1 and y1 are not limited to the above-mentioned values, other suitable values of x1 and y1 may be adapted in this disclosure.

Although an atom radius of aluminum (Al) is 125 pm which is smaller than that of gallium, the atom radius of aluminum is larger than that of silicon. Accordingly, aluminium dopant in the second nitride semiconductor layers 244 can slow down the increasing of the stress. Therefore, the crack possibility of the nitride semiconductor device 200 can be lowered.

In addition, a content of Al in the plurality of n-Alₓ₁Ga_{y1}N layers is between about 2% and about 10%. When the content of Al in the plurality of n-Alₓ₁Ga_{y1}N layers is between about 2% and about 10%, aluminium in the second nitride semiconductor layers 244 can effectively slow down the increasing of the stress as the first nitride semiconductor layers 242 is the n-GaN layers. When the content of Al in the plurality of n-Alₓ₁Ga_{y1}N layers increases, the stress would be changed rapidly, and the crack possibility of the second nitride semiconductor layers 244 might be increased. Therefore, if the content of Al in the plurality of the second nitride semiconductor layers 244 (the n-AlGaN layers) is unduly high, the thickness of each of the second nitride semiconductor layers 244 becomes thin. The bonding energy of Al—N is higher than that of Ga—N so that it is difficult to dope the n-type dopant (silicon) in the Al—N structure to form n-AlGaN. In this embodiment, the content of Al in the plurality of n-Alₓ₁Ga_{y1}N layers is about 8% which provides better effect to slow down the increasing of the stress.

Moreover, a lattice constant of the n-GaN layers is between about 3.188 Å and about 3.189 Å, and a lattice constant of the n-AlGaN layer is between about 3.175 Å and about 3.18 Å. A difference between the lattice constant of the plurality of first nitride semiconductor layers 242 and the lattice constant of the plurality of second nitride semiconductor layers 244 is between about 0.28% and about 0.44%. The difference between the lattice constant of the plurality of first nitride semiconductor layers 242 and the lattice constant of the plurality of second nitride semiconductor layers 244 slow down the increasing of the stress and effectively minimize the crack possibility of the nitride semiconductor device 200. The different lattice between the lattice mismatch pair (the consecutive layer) will cause the stress in the opposite direction to mitigate the stress in each other.

In order to observe the difference of the surface conditions between the conventional nitride semiconductor device and the nitride semiconductor device having the lattice mismatch pairs and the difference between the nitride semiconductor devices having different amounts of the lattice mismatch pairs. FIG. 2B is an optical microscope (OM) picture of the conventional nitride semiconductor device. FIG. 2C is an optical microscope picture of a nitride semiconductor device with one lattice mismatch pair. FIG. 2D is an optical microscope picture of the nitride semiconductor device of FIG. 2A. FIG. 2B, FIG. 2C and FIG. 2D are 5× optical microscope pictures of surfaces of the conventional nitride semiconductor device 100, a nitride semiconductor device with one lattice mismatch pair and the nitride semiconductor device 200. In FIG. 2B, a lot of cracks are formed on the surface of the conventional nitride semiconductor device 100. In FIG. 2C, the amounts of cracks are reduced. In FIG. 2D, no crack is formed on the surface of the nitride semiconductor device 200. Therefore, the first type nitride semiconductor stacked layer 240 can effectively minimize the crack possibility.

In this embodiment, The first type nitride semiconductor stacked layer 240 comprises the first nitride semiconductor layers 242 and the second nitride semiconductor layers 244, wherein the material of the second nitride semiconductor layers 244 comprise n-AlGaN. The difference between the lattice constant of the plurality of first nitride semiconductor layers 242 and the lattice constant of the plurality of second nitride semiconductor layers 244 slow down the increasing of the stress. Therefore, the crack possibility of the nitride semiconductor device 200 can be minimized and the thickness of the first type nitride semiconductor stacked layer 240 can be increased. In another embodiment, the buffer layer 230 also can be replaced by another lattice mismatch pairs structure so as to slow down the increasing of the stress.

Besides, a thickness of each of the first nitride semiconductor layers 242 is between about 20 nm and about 30 nm, and a thickness of each of the second nitride semiconductor layers 244 is between about 20 nm and about 30 nm. In this embodiment, the thicknesses of each of the first nitride semiconductor layers 242 and each of the second nitride semiconductor layers 244 are both 25 nm, respectively, for example. However, the thicknesses of each of the first nitride semiconductor layers 242 and each of the second nitride semiconductor layers 244 are not limited to the above-mentioned values, other suitable values may be adapted in this disclosure. When the content of Al in the plurality of n-Alₓ₁Ga_{y1}N layers is 8%, each of the second nitride semiconductor layers 244 is about 25 nm, and the concentrations of the n-type dopants in each of the first nitride semiconductor layers 242 and the second nitride semiconductor layers 244 are about 2×10¹⁸/cm³.

Moreover, at least 5 pairs of the first nitride semiconductor layers 242 and the second nitride semiconductor layers 244 are stacked. In this embodiment, 10 pairs of the first nitride semiconductor layers 242 and the second nitride semiconductor layers 244 are stacked, for example. However, number of the pairs of the first nitride semiconductor layers 242 and the second nitride semiconductor layers 244 are not limited to the above-mentioned value, other suitable value may be adapted in this disclosure.

In addition, a total thickness of the plurality of first nitride semiconductor layers 242 is between about 200 nm and about 2000 nm, and a total thickness of the plurality of second nitride semiconductor layers 244 is between about 200 nm and about 2000 nm. In this embodiment, the total thickness of the first nitride semiconductor layers 242 is about 250 nm, and the total thickness of the second nitride semiconductor layers 244 is about 250 nm. The thickness of the first type nitride semiconductor stacked layer 240 is between about 0.2 μm and about 4 μm. In this embodiment, the thickness of the first type nitride semiconductor stacked layer 240 is about 0.5 μm, for example. However, the thickness of the first type nitride semiconductor stacked layer 240 is not limited to the above-mentioned value, other suitable value may be adapted in this disclosure.

FIG. 2E is a raman spectrum of the conventional nitride semiconductor device. FIG. 2F is a raman spectrum of the nitride semiconductor device of FIG. 2A. Comparing to FIG. 2E and FIG. 2F, a raman shift of a peak of the conventional nitride semiconductor device 100 is from 566.5 cm-1 to 565.5 cm-1, and a raman shift of a peak of the nitride semiconductor device 200 is from 566.5 cm-1 to 567 cm-1.

In this embodiment, because of the following conditions, the increasing of the stress generated by the n-type dopant can be effectively slowed down. First, the difference between the lattice constants of the first nitride semiconductor layers 242 and the second nitride semiconductor layers 244 is between 0.28%˜0.44%. Second, the total thicknesses of the first nitride semiconductor layers 242 and the second nitride semiconductor layers 244 are between about 200 nm and about 2000 nm. Third, the number of the lattice mismatch pairs is at lest 5. Because each of the lattice mismatch pairs comprises the first nitride semiconductor layers 242 and the second nitride semiconductor layers 244, the difference between the lattice constant of the plurality of first nitride semiconductor layers 242 and the lattice constant of the plurality of second nitride semiconductor layers 244 slow down the increasing of the stress generated by the n-type dopant. Even during the cooling process, the crack possibility in the nitride semiconductor device 200 can be minimized, and internal quantum efficiency (IQE) of the nitride semiconductor device 200 can be further improved.

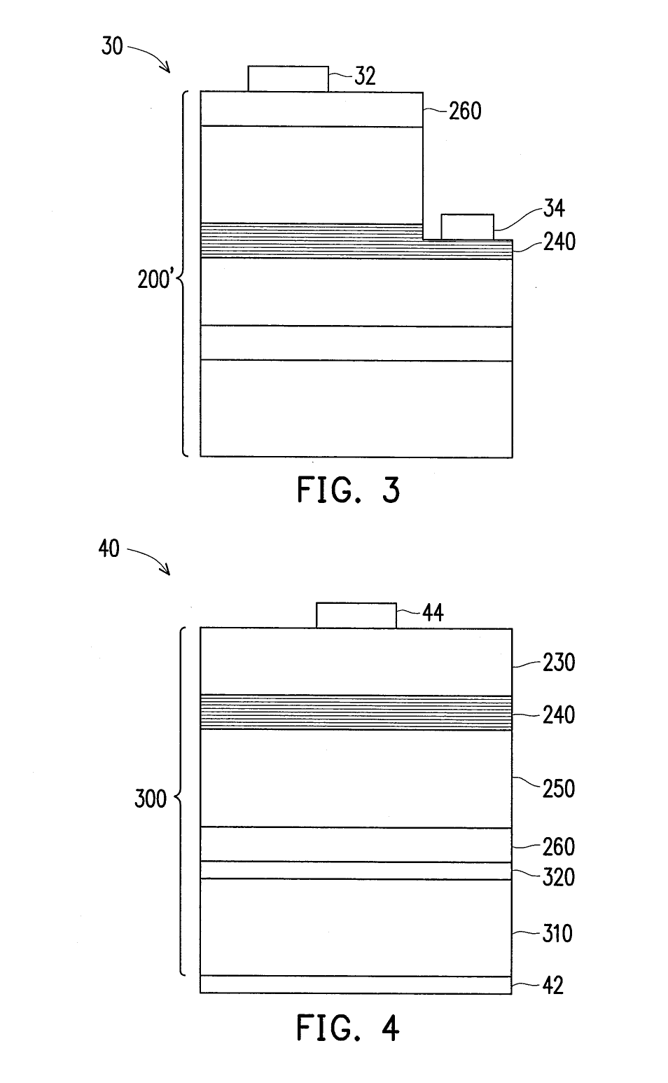

The nitride semiconductor device 200 can apply for a LED device. FIG. 3 is a cross-sectional view schematically illustrating an LED according the first embodiment of the disclosure. Referring to FIG. 3, a LED device 30 comprises the nitride semiconductor device 200′ and two electrodes 32, 34. One electrode 32 is disposed on the second type nitride semiconductor layer 260, and the other electrode 34 is disposed on the first type nitride semiconductor stacked layer 240. Although the nitride semiconductor device 200′ is used in LED device 30, the type of the nitride semiconductor device is not limited in the nitride semiconductor device 200′, other suitable nitride semiconductor device may be adapted in this disclosure.

FIG. 4 is a cross-sectional view schematically illustrating an LED according the second embodiment of the disclosure. Referring to FIG. 4, a LED device 40 comprises a nitride semiconductor device 300 and two electrodes 42, 44. The nitride semiconductor device 300 which is formed by inverting the nitride semiconductor device 200 of FIG. 2A over a silicon substrate 310 and a reflective bonding layer 320 and removing the silicon substrate 210 and the nucleation layer 220. The second type nitride semiconductor layer 260 of the nitride semiconductor device 300 contacts with the reflective bonding layer 320. The electrodes 42 is disposed under the silicon substrate 310, and the electrodes 44 is disposed on the buffer layer 230 of the nitride semiconductor device 300 as shown in FIG. 4. Although the LED device 40 is formed by the nitride semiconductor device 300, the LED device 40 can also be formed by other suitable nitride semiconductor device in this disclosure.

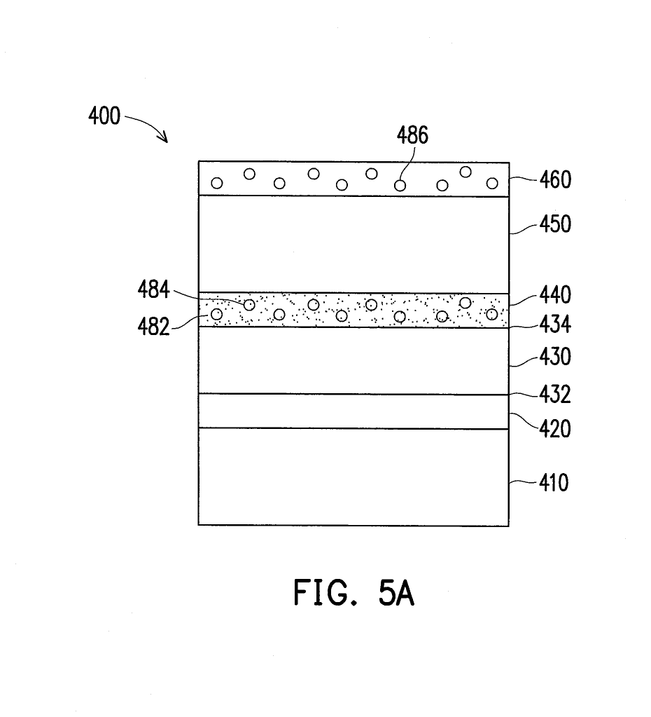

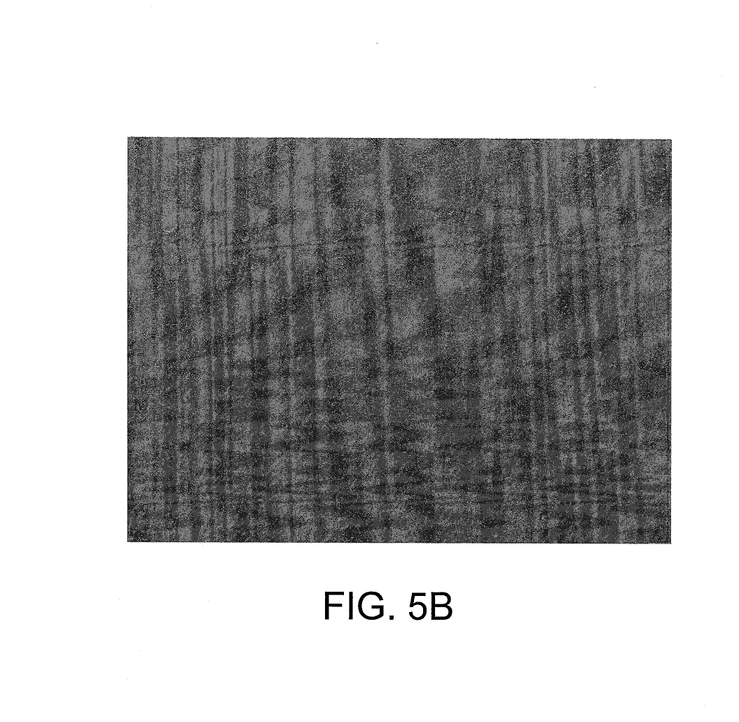

FIG. 5 is a cross-sectional view schematically illustrating a nitride semiconductor device according to the second embodiment of the disclosure. Referring to FIG. 5, the nitride semiconductor device 400 comprises a silicon substrate 410, a nucleation layer 420, a buffer layer 430, a first type nitride semiconductor layer 440, a light-emitting layer 450 and a second type nitride semiconductor layer 460. The nucleation layer 420 is disposed on the silicon substrate 410. The buffer layer 430 is disposed on the nucleation layer 420. The first type nitride semiconductor layer 440 is disposed on the buffer layer 430. The first type nitride semiconductor layer 440 is doped with a first type dopant 482, and at least one of the buffer layer 430 and the first type nitride semiconductor layer 440 comprises a codopant 484 distributed therein, and an atomic radius of the codopant 484 is larger than an atomic radius of the first type dopant 442. In this embodiments, the first type nitride semiconductor layer 440 comprises the codopant 484 distributed therein. The light-emitting layer 450 is disposed on the first type nitride semiconductor layer 440. A second type nitride semiconductor layer 460 is disposed on the light-emitting layer 450, and the second type nitride semiconductor layer 460 comprises a second type dopant 486.

In this embodiments, the buffer layer 430 comprises a graded AlGaN layer, a content of Al of the graded AlGaN layer gradually decreases from a first surface 432 of the buffer layer 430 to a second surface 434 of the buffer layer 430, the first surface 432 is in contact with the nucleation layer 420, and the second surface 434 is in contact with the first type nitride semiconductor layer 440. The variation rate of lattice constant divided by the thickness of the buffer layer 430 (the graded AlGaN layer) is from 5.08%/μm to 1.27 μm.

The first type dopant 482 is selected from elements of group IV A, the second type dopant 486 is selected from elements of group II A, and the codopant 484 is selected from elements which have larger atom radius than the first type dopant 482, such as elements of group II A or IIIA. In this embodiment, the first type dopant 482 is silicon (Si), and the codopant 484 and the second type dopant 486 are magnesium (Mg) or indium (In), for example. However, the first type dopant, the codopant 484 and the second type dopant 486 are not limited to the above elements, other suitable elements may be used in this embodiment.

In FIG. 5, the first type dopant 482 and the codopant 484 are doped into the first type nitride semiconductor layer 440. The atomic radius of the first type dopant 482 may be between about 105 pm and about 115 pm, and the atomic radius of the codopant 484 may be between about 150 pm and about 160 pm. In this embodiment, because the atom radius of the codopant 484 (magnesium) is 150 pm which is larger than that of the first type dopant 482 (silicon), the codopant 484 in the buffer layer 430 can slow down the increasing of a stress. Therefore, the crack possibility of the nitride semiconductor device 400 can be minimized, and a thickness of the first type nitride semiconductor layer 440 can be increased. In this embodiment, the thickness of the first type nitride semiconductor layer 440 is larger than about 1 μm.

An atom percentage of the codopant 484 may be smaller than 1%. A concentration of the first type dopant 482 may be between about 5×10¹⁷/cm³ and about 5×10¹⁸/cm³, and a concentration of the codopant 484 may be between about 5×10¹⁸/cm³ and about 5×10¹⁹/cm³. Because the concentration of the codopant 484 in the first type nitride semiconductor layer 440 is light, the concentration of the electron in the first type nitride semiconductor layer 440 would not be influenced by the codopant 484. On the contrary, the concentration of the electron even can become twice because the stress can be slowed down.

A main difference between the nitride semiconductor device 400 of FIG. 5 and the nitride semiconductor device 200 of FIG. 2A is as below. In the nitride semiconductor device 200 of FIG. 2A, the increasing of the stress generated by the n-type dopant is slowed down by the first type nitride semiconductor stacked layer 240 which comprises the second nitride semiconductor layers 244 having aluminium and silicon dopant distributed therein. In the nitride semiconductor device 400 of FIG. 5, the increasing of the stress generated by the first type dopant 482 is slowed down by the codopant 484 distributed within the first type nitride semiconductor layer 440.

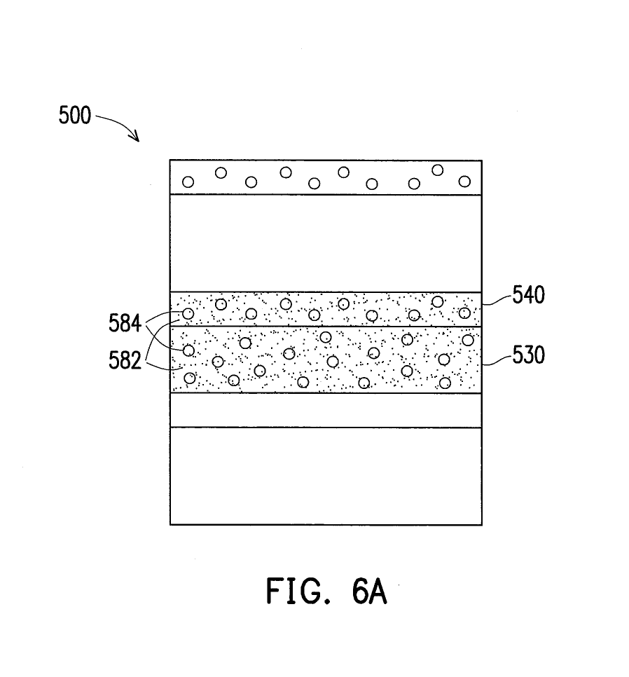

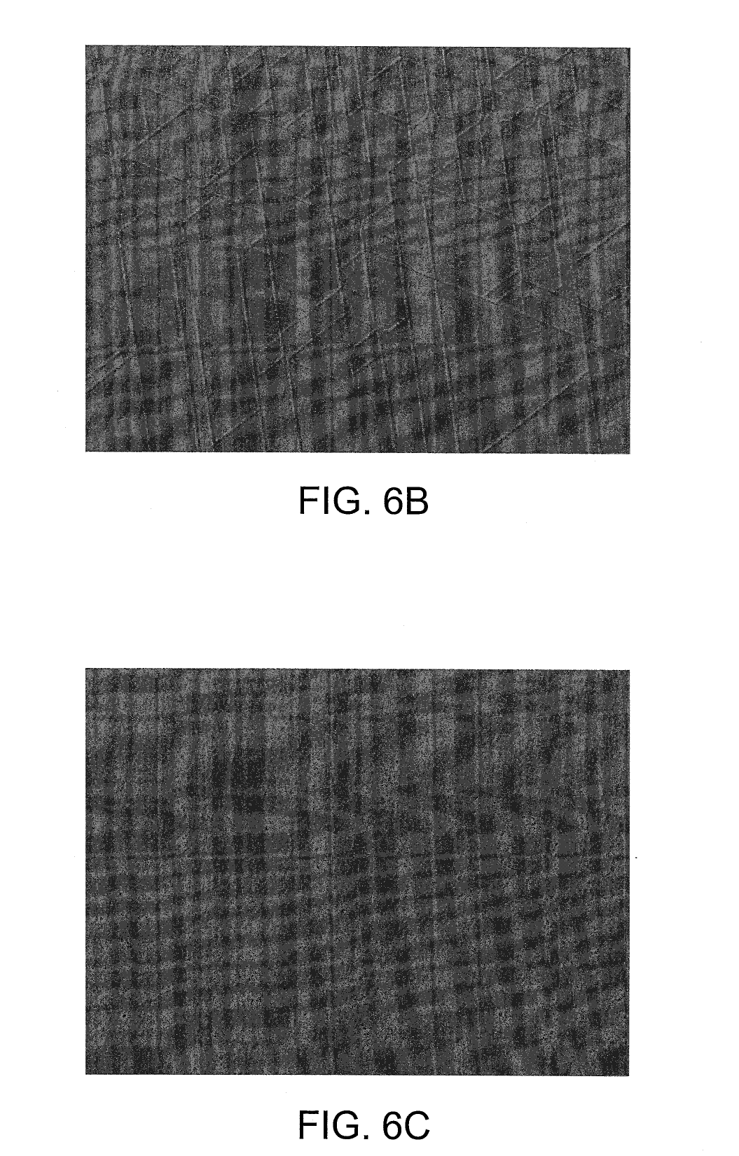

FIG. 6A is a cross-sectional view schematically illustrating a nitride semiconductor device according to the third embodiment of the disclosure. Referring to FIG. 6A, a main difference between the nitride semiconductor device 500 of FIG. 6 and the nitride semiconductor device 400 of FIG. 5 is that the first type nitride semiconductor layer 540 of the nitride semiconductor device 500 in FIG. 6 comprises an n-GaN layer having the first type dopant 582 and the codopant 584 distributed therein. In this embodiment, the first type dopant 582 is silicon, the codopant 584 is magnesium, for example. However, the first type dopant 582 and the codopant 584 are not limited to the above elements, other suitable elements may be used in this embodiment.

In the embodiment, the buffer layer 530 comprises a graded AlGaN layer having the first type dopant 582 and the codopant 584 distributed therein, and the first type nitride semiconductor layer 540 comprises an n-GaN layer having the first type dopant 582 and the codopant 584 distributed therein. In this embodiment, a content of Al of the graded AlGaN layer in the buffer layer 530 is gradually varied as that in the buffer layer 430. The variation rate of lattice constant divided by the thickness of the buffer layer 530 (the graded AlGaN layer) is from 5.08%/μm to 1.27%/μm. The increasing of the stress generated by the first type dopant 582 can be slowed down by the codopant 584 distributed in the buffer layer 530 and the first type nitride semiconductor layer 540. Therefore, the crack possibility of the nitride semiconductor device 500 can be minimized, and a thickness of the first type nitride semiconductor layer 540 can be increased.

FIG. 5B is an optical microscope picture of the nitride semiconductor device of FIG. 5A after growing the first type nitride semiconductor layer. FIG. 6B is an optical microscope picture of the conventional nitride semiconductor device after growing the first type nitride semiconductor layer. FIG. 6C is an optical microscope picture of the nitride semiconductor device of FIG. 6A after growing the first type nitride semiconductor layer. Referring to FIG. 5B, FIG. 6B and FIG. 6C, they are 5× optical microscope pictures of the conventional nitride semiconductor device 100, the nitride semiconductor device 400 and the nitride semiconductor device 500 after growing the first type nitride semiconductor layer. In FIG. 6B, crack is formed on the surface, and the surface is quite rough. In FIG. 5B, no crack is formed on the surface, and the surface roughness is reduced. In FIG. 6C, the surface is smooth. Therefore, the first dopant and the codopant can effectively minimize the surface roughness.

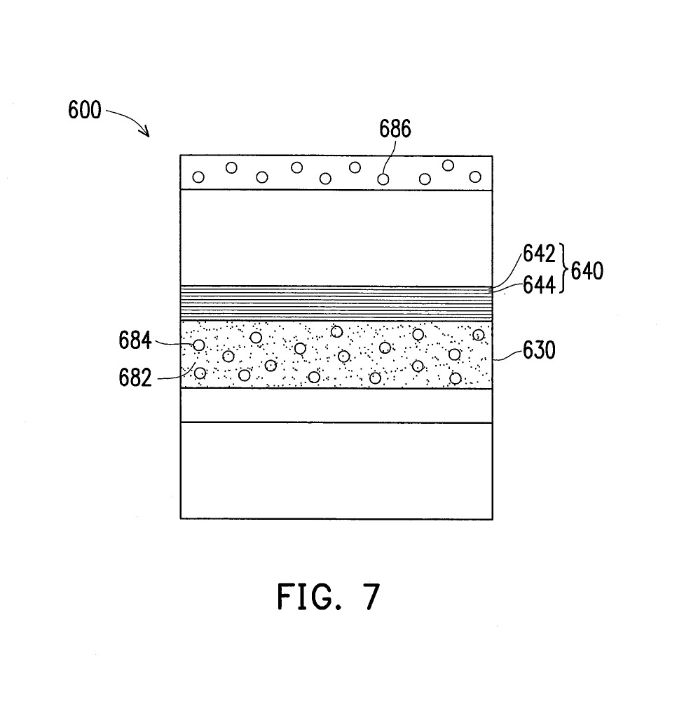

FIG. 7 is a cross-sectional view schematically illustrating a nitride semiconductor device according to the fifth embodiment of the disclosure. Referring to FIG. 7, a main difference between the nitride semiconductor device 600 of FIG. 7 and the nitride semiconductor device 400 of FIG. 5 is that the first type nitride semiconductor layer 640 of the nitride semiconductor device 600 in FIG. 7 is a lattice mismatch stacked layer comprising a plurality of first nitride semiconductor layers 642 and a plurality of second nitride semiconductor layers 644. The first nitride semiconductor layers 642 and the second nitride semiconductor layers 644 are stacked alternately. The first nitride semiconductor layers 642 comprise a plurality of n-GaN layers, a plurality of n-AlGaN layers or a plurality of n-InGaN layers, the second nitride semiconductor layers 644 comprise a plurality of n-GaN layers, a plurality of n-AlGaN layers or a plurality of n-InGaN layers, and the first nitride semiconductor layers 642 and the second nitride semiconductor layers 644 are different material. In this embodiment, the first nitride semiconductor layers 642 comprise n-GaN layers, and the second nitride semiconductor layers 644 comprise n-AlGaN layers.

In the embodiment, the buffer layer 630 comprises a graded AlGaN layer having the first type dopant 682 and the codopant 684 distributed therein. In this embodiment, a content of Al of the graded AlGaN layer in the buffer layer 630 is gradually varied as that in the buffer layer 430. The variation rate of lattice constant divided by the thickness of the buffer layer 630 (the graded AlGaN layer) is from 5.08%/μm to 1.27%/μm. The first type dopant 682 is selected from elements of group IV A, and the codopant 684 is selected from elements which have larger atom radius, such as elements of group II A. In this embodiment, the first type dopant 682 is silicon, the codopant 684 is magnesium, for example. However, the first type dopant 682 and the codopant 684 are not limited to the above elements, other suitable elements may be used in this embodiment. Besides, the first nitride semiconductor layers 642 comprise the plurality of n-GaN layers, and the second nitride semiconductor layers 644 comprise the plurality of n-AlGaN layers. The increasing of the stress generated by the first type dopant 682 can be slowed down by the codopant 684 in the buffer layer 630, and if the aluminium to be a dopant in the second nitride semiconductor layers 644 simultaneously, the possibility of the crack formed of the nitride semiconductor device 600 is mitigated further, and a thickness of the first type nitride semiconductor layer 640 can be increased.

Certainly, in another embodiments, the nitride semiconductor devices can use the nitride semiconductor device 500 in FIG. 6 and replace the buffer layer 530 with the lattice mismatch stacked layer which comprises a plurality of first nitride semiconductor layers and a plurality of second nitride semiconductor layers stacked alternately. The crack possibility of these nitride semiconductor device can be further minimized by the lattice mismatch stacked layer and the first type nitride semiconductor layer 540. Besides, not only the nitride semiconductor devices 200 but also the nitride semiconductor devices 400, 500, 600 can apply for the LED device.

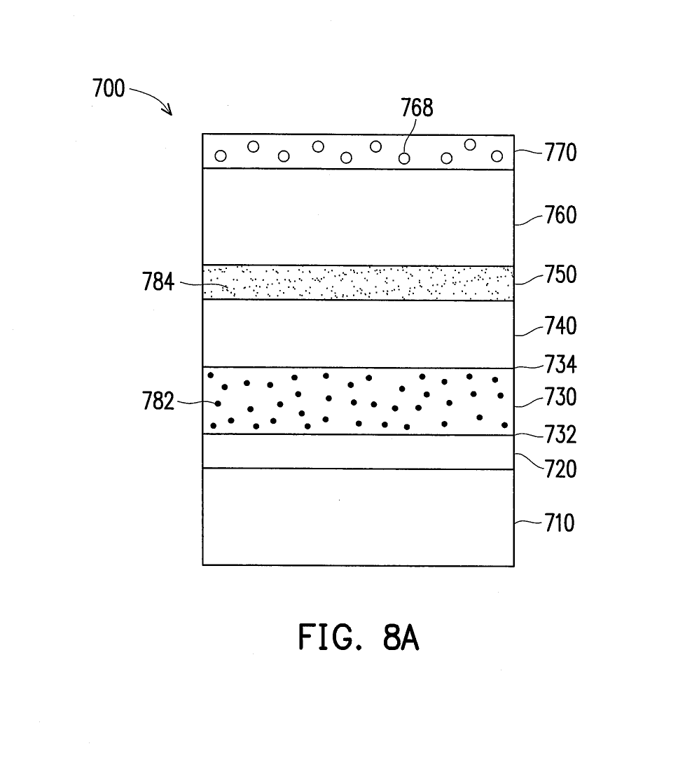

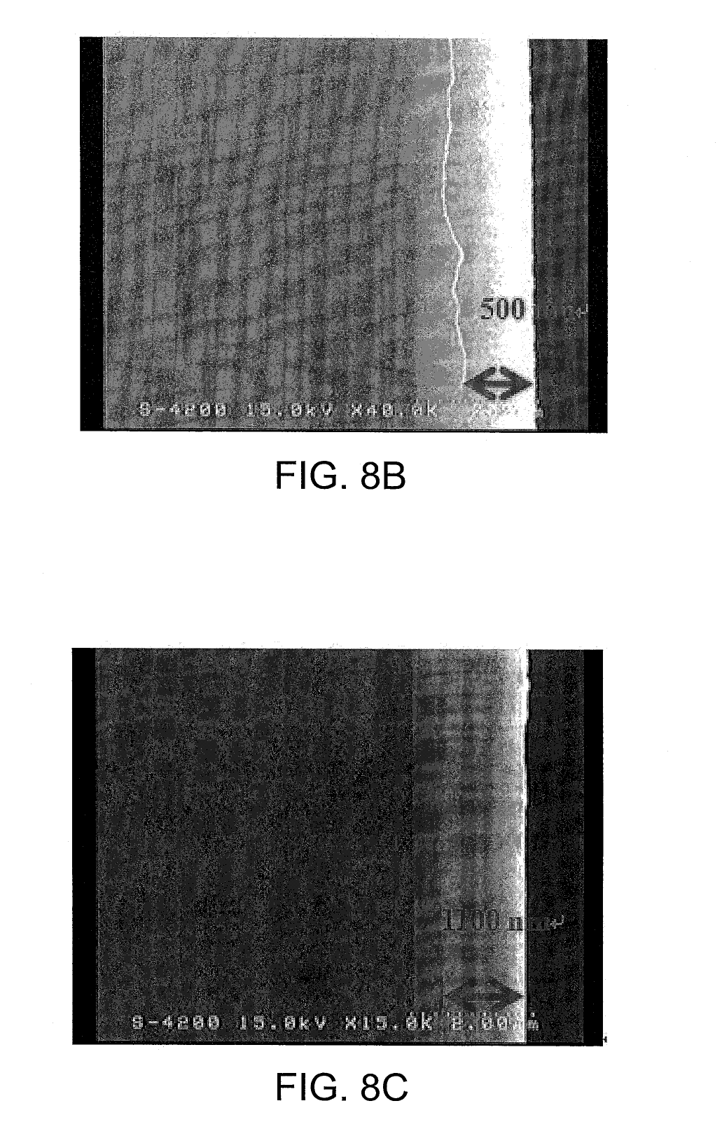

FIG. 8A is a cross-sectional view schematically illustrating a nitride semiconductor device according to the sixth embodiment of the disclosure. Referring to FIG. 8A, the nitride semiconductor device 700 comprises a silicon substrate 710, a nucleation layer 720, a first buffer layer 730, a first type nitride semiconductor layer 750, a light-emitting layer 760 and a second type nitride semiconductor layer 770. The nucleation layer 720 is disposed on the silicon substrate 710. The first buffer layer 730 is disposed on the nucleation layer 720. The first buffer layer 730 comprises a dopant 782 and gallium (Ga), an atomic radius of the dopant 782 is larger than an atomic radius of gallium. The first type nitride semiconductor layer 750 is disposed over the first buffer layer 730. The light-emitting layer 760 is disposed on the first type nitride semiconductor layer 750. The second type nitride semiconductor layer 770 is disposed on the light-emitting layer 760.

In this embodiment, the first buffer layer 730 comprises a graded AlGaN layer, a content of Al of the graded AlGaN layer decreases from a first surface 732 of the first buffer layer 730 to a second surface 734 of the first buffer layer 730, the first surface 732 is in contact with the nucleation layer 720, and the second surface 734 is away from the nucleation layer 720.

The dopant 782 is selected from elements which have larger atom radius. In this embodiment, the dopant 782 is indium (In), but it also can be magnesium (Mg) or other element selected from elements whose atom radius is larger than gallium. The material of the light-emitting layer 760 comprises indium, for example the light-emitting layer 760 comprises InGaN. Therefore, the dopant 782 and at least one element of the light-emitting layer 760 are the same. In this embodiment, an atom percentage of the dopant 782 in the first buffer layer 730 is less than 1%.

In addition, The first type nitride semiconductor layer 750 comprises a first type dopant 784, and the second type nitride semiconductor layer 770 comprises a second type dopant 786. The first type dopant 784 is selected from elements of group IV A, and the second type dopant 768 is selected from elements of group II A. The first type dopant 784 may be silicon, and the second type dopant 768 may be magnesium, for example.

The atomic radius of the dopant 782 may be between about 150 pm and about 160 pm. The atomic radius of the dopant 782 (the atomic radius of indium is 156 pm) is larger than the atomic radius of gallium (130 pm). In this embodiment, the nitride semiconductor device 700 further comprises a second buffer layer 740 disposed between the first buffer layer 730 and the first type nitride semiconductor layer 750. Lattice dimensions of the nucleation layer 720 and the second buffer layer 740 are respectively about 3.112 Å and 3.189 Å, and a lattice dimension of the first buffer layer 730 is larger than 3.189 Å. The lattice constants of (0001) AlN and (0001) GaN in a-axis are 3.11 Å and 3.189 Å, respectively. The variation rate of lattice constant in percentage (%) is equal to

$$\frac{GaN - AlN}{AlN} \times 100 \% = \frac{3.189 - 3.11}{3.11} \times 100 \% = 2.54 \% .$$

The variation rate of lattice constant divided by the thickness of the first buffer layer 730 (the graded AlGaN layer) is from 5.08%/μm to 1.27%/μm. The structure having the variation rate in the lattice constant may reduce stress built in epitaxy layers and improve the crystal quality. The increasing of the stress can be slowed down by the first buffer layer 730 having the dopant 782 distributed therein. Therefore, the crack possibility of the nitride semiconductor device 700 can be minimized effectively, and the thickness of the second buffer layer 740 may be increased. In this embodiment, the second buffer layer 740 comprises an un-doped GaN layer, and a thickness of the second buffer layer 740 is not more than 1 μm.

In another embodiment, the dopant 782 is not only doped in the first buffer layer 730 but also doped in the second buffer layer 740, the first type nitride semiconductor layer 750 or both the second buffer layer 740 and the first type nitride semiconductor layer 750, so that the increasing of the stress can be slowed down and the crack possibility of the nitride semiconductor device 700 can be minimized.

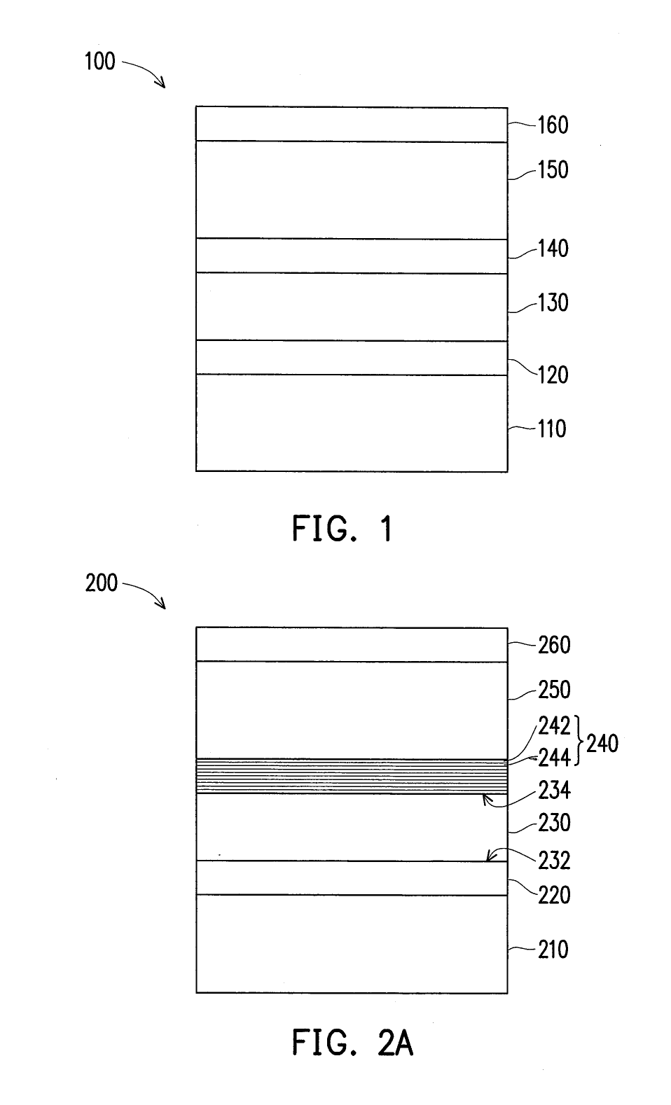

FIG. 8B is a scanning electron microscope (SEM) picture of the conventional nitride semiconductor device (as shown in FIG. 1). FIG. 8C is a scanning electron microscope (SEM) picture of the nitride semiconductor device of FIG. 8A. Referring to FIG. 1, FIG. 8B and FIG. 8C, the thickness of the second buffer layer 740 of the nitride semiconductor device 700 is approximately twice than that of the first type nitride semiconductor layer 140 of the conventional nitride semiconductor device 100. Therefore, the dopant 782 and gallium in the first buffer layer 730 can effectively improve the thickness of the first type nitride semiconductor layer 750.

A main differences between the nitride semiconductor device 200 of FIG. 2A, the nitride semiconductor device 400 of FIG. 5 and the nitride semiconductor device 700 of FIG. 8A are as below. In the nitride semiconductor device 200 of FIG. 2A, the increasing of the stress generated by the n-type dopant is slowed down by the first type nitride semiconductor stacked layer 240 which comprises the second nitride semiconductor layers 244 having aluminium and silicon dopant distributed therein. In the nitride semiconductor device 400 of FIG. 5, the increasing of the stress generated by the first type dopant 482 is slowed down by the codopant 484 distributed within the first type nitride semiconductor layer 440. In the nitride semiconductor device 700 of FIG. 8A, the increasing of the stress generated by the first type dopant 784 is slowed down by the dopant 782 distributed within the first buffer layer 730. Although the increasing of the stress in FIG. 2A, FIG. 5 and FIG. 8A are slowed down by different layer of the nitride semiconductor device 200, 400, 700, the crack possibility of the nitride semiconductor device 200, 400, 700 can be both minimized.

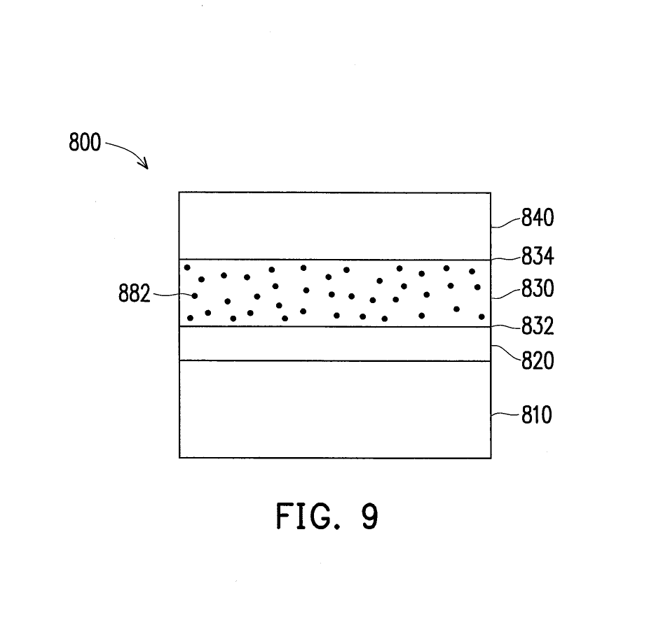

The nitride semiconductor device may apply for a LED device or a power device. FIG. 9 is a cross-sectional view schematically illustrating a nitride semiconductor device according to the seventh embodiment of the disclosure. Referring to FIG. 9, the nitride semiconductor device 800 comprises a silicon substrate 810, a nucleation layer 820, a first buffer layer 830 and a second buffer layer 840. The nucleation layer 820 is disposed on the silicon substrate 810. The first buffer layer 830 is disposed on the nucleation layer 820. The second buffer layer 840 is disposed on the first buffer layer 830.

In this embodiment, the first buffer layer 830 comprises a graded AlGaN layer, a content of Al of the graded AlGaN layer gradually decreases from a first surface 832 of the first buffer layer 830 to a second surface 834 of the first buffer layer 830, the first surface 832 is in contact with the nucleation layer 820, and the second surface 834 is in contact with the second buffer layer 840. The variation rate of lattice constant divided by the thickness of the first buffer layer 830 (the graded AlGaN layer) is from 5.08%/μm to 1.27%/μm. Besides, the first buffer layer 830 comprises a dopant 882 and gallium, an atomic radius of the dopant 882 is larger than an atomic radius of gallium. The second buffer layer 840 comprises an un-doped GaN layer. The nitride semiconductor device 800 may be a substrate preparing for the formation of the power device, for example: HEMT or MOS transistor or MOSFET. However, the application of the nitride semiconductor device 900 are not limited to HEMT or MOS transistor or MOSFET, other suitable applications of compound semiconductor transistors may be used in this embodiment.

Because the first buffer layer 830 having the dopant 882 distributed therein, the increasing of the stress generated from the difference thermal expansion coefficient of the silicon substrate 810 and the first buffer layer 830 (the nitride compounds) can be slowed down by the dopant 882. Therefore, the crack possibility of the power device can be prevented.

According to the aforementioned embodiments, the increasing of the stress can be slowed down by the first type nitride semiconductor stacked layer, the codopant distributed within at least the buffer layer or the first type nitride semiconductor layer, and the dopant distributed within the first buffer layer. Therefore, the crack possibility of the nitride semiconductor device can be minimized and the thickness of the nitride semiconductor device can be increased.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A nitride semiconductor device, comprising:
a silicon substrate;
a nucleation layer disposed on the silicon substrate;
a buffer layer disposed on the nucleation layer;
a first type nitride semiconductor layer disposed on the buffer layer, wherein the first type nitride semiconductor layer is doped with a first type dopant, at least one of the buffer layer and the first type nitride semiconductor layer comprises a codopant distributed therein, and an atomic radius of the codopant is larger than an atomic radius of the first type dopant;
a light-emitting layer disposed on the first type nitride semiconductor layer; and
a second type nitride semiconductor layer disposed on the light-emitting layer, the second type nitride semiconductor layer comprising a second type dopant.

2. The nitride semiconductor device as recited in claim 1, wherein the first type dopant is selected from elements of group IV A, and the codopant is selected from elements of group II A.

3. The nitride semiconductor device as recited in claim 1, wherein each of the second type dopant and the codopant is selected from elements of group II A.

4. The nitride semiconductor device as recited in claim 1, wherein the atomic radius of the first type dopant is between about 105 and about 115 pm, and the atomic radius of the codopant is between about 150 and about 160 pm.

5. The nitride semiconductor device as recited in claim 1, wherein the codopant is magnesium.

6. The nitride semiconductor device as recited in claim 1, wherein a concentration of the first type dopant is between about 5×10¹⁷/cm³ and about 5×10¹⁸/cm³, and a concentration of the codopant is between about 5×10¹⁸/cm³ and about 5×10¹⁹/cm³.

7. The nitride semiconductor device as recited in claim 1, wherein a thickness of the first type nitride semiconductor layer is larger than about 2 μm.

8. The nitride semiconductor device as recited in claim 1, wherein an atom percentage of the codopant is smaller than 1%

9. The nitride semiconductor device as recited in claim 1, wherein the buffer layer comprises a graded AlGaN layer having the first type dopant and the codopant therein, a content of Al of the graded AlGaN layer decreases from a first surface of the buffer layer to a second surface of the buffer layer, the first surface is in contact with the nucleation layer, and the second surface is in contact with the first type nitride semiconductor layer.

10. The nitride semiconductor device as recited in claim 9, wherein the first type nitride semiconductor layer comprises an n-GaN layer having the codopant distributed therein.

11. The nitride semiconductor device as recited in claim 9, wherein the first type nitride semiconductor layer is a lattice mismatch stacked layer comprising a plurality of first nitride semiconductor layers and a plurality of second nitride semiconductor layers, the first nitride semiconductor layers and the second nitride semiconductor layers are stacked alternately.

12. The nitride semiconductor device as recited in claim 11, wherein the first nitride semiconductor layers comprise a plurality of n-GaN layers, a plurality of n-AlGaN layers or a plurality of n-InGaN layers, the second nitride semiconductor layers comprise a plurality of n-GaN layers, a plurality of n-AlGaN layers or a plurality of n-InGaN layers, and the first nitride semiconductor layers and the second nitride semiconductor layers are different material.

13. The nitride semiconductor device as recited in claim 1, wherein the first type nitride semiconductor layer comprises an n-GaN layer having the codopant distributed therein.

14. The nitride semiconductor device as recited in claim 1, wherein the buffer layer comprises an un-doped GaN layer, and the first type nitride semiconductor layer comprises an n-GaN layer having the codopant distributed therein.
